(19) United States
(12) Patent Application Publication
(10) Pub. No.: US 2021/0233942 A1
(43) Pub. Date: Jul. 29, 2021

(54) ARRAY SUBSTRATE, MANUFACTURING METHOD AND DISPLAY THEREOF

(71) Applicant: Shenzhen China Star Optoelectronics Semiconductor Display Technology Co., Ltd., Shenzhen, Guangdong (CN)

(72) Inventors: Hui XIA, Shenzhen, Guangdong (CN); Zhiwei TAN, Shenzhen, Guangdong (CN)

(21) Appl. No.: 16/304,342

(22) PCT Filed: Aug. 30, 2018
(86) PCT No.: PCT/CN2018/103290

§ 371 Date: Nov. 26, 2018

(30) Foreign Application Priority Data
Jun. 25, 2018 (CN) 201810659928.9

(51) Int. Cl. H01L 27/12; C09D 11/52; G03F 7/09; G03F 7/095; G03F 7/42; G03F 7/00; H01L 29/786

(52) U.S. Cl. CPC H01L 27/1288; C09D 11/52; G03F 7/094; G03F 7/095; B82Y 20/00; G03F 7/0035; H01L 27/1218; H01L 27/1262; H01L 29/78645; G03F 7/42

(57) ABSTRACT

An array substrate, a manufacturing method and a display panel thereof are provided. A single mask process is used for completing formation of a flat layer and a pixel definition layer, or the flat layer, the pixel definition layer and a spacer. A light emitting unit is located within an anode so that the light of the emitting unit is reflected by the anode to accumulate. The risk of color mixing on the display panel is reduced, and the light intensity on the light exit side is enhanced.

### BACKGROUND OF THE DISCLOSURE

### 1. Field of the Disclosure

The present disclosure is related to the field of panel manufacturing, and in particular to an array substrate, a manufacturing method and a display panel thereof.

### 2. Description of the Related Art

Currently, as a one-dimensional nanomaterial, carbon nanotubes are light in weight and have a perfect hexagonal structure. Since the structure of carbon nanotubes is the same as the layer structure of graphite, the carbon nanotubes have good electrical properties. In the field of existing display panel manufacturing, a film made of randomly oriented carbon nanotube nets is often used as an active layer in an array substrate.

In addition, since an n-type carbon nanotube thin film transistor which has a carbon nanotube film used as an active layer generally has a high Ioff current, a semiconductor material with a high electron concentration is usually added between the source/drain electrode and the carbon nanotube thin film active layer, so as to reduce the hole current, thereby to achieve the reduction of loff. However, since the n-type carbon nanotube active layer is thin, it cannot be processed in a manner like that of the amorphous silicon thin film transistor device: the ohmic contact layer on the active layer is etched to have the ohmic contact layer be patterned.

Thus, a simple, low-cost manufacturing method for an n-type carbon nanotube TFT with ohmic contact layer materials is important.

### SUMMARY

An array substrate, a manufacturing method and a display panel thereof are provided, so as to simplify the preparing process of the array substrate in the prior art and reduce the cost.

In order to achieve the above objective, the technical solutions provided by the present disclosure are as follows:

A manufacturing method for array substrate, includes:
S10. providing a substrate, forming a first metal layer on the substrate, and forming a gate of the array substrate on the substrate via a patterning process;
S20. forming a gate insulating layer on the gate;
S30. forming an active layer on the gate insulating layer;
S40. forming a first photoresist layer having a predetermined pattern on the active layer;
S50. forming an ohmic contact layer and second metal layer on the first photoresist layer sequentially;
S60. stripping the first photoresist layer; and
S70. forming a passivation layer on the second meatal layer.

In the manufacturing method, the step S10, includes:
S101. providing the substrate, forming the first metal layer on the substrate;
S102. forming a second photoresist layer on the first metal layer;
S103. exposing and developing the second photoresist layer;
S104. performing a first etching process on the first metal layer to cause the first metal layer to form the gate of the array substrate; and
S105. stripping the second photoresist layer.

In the manufacturing method, the step S30, includes:
S301. forming the active layer on the gate insulating layer;
S302. exposing and developing the third photoresist layer;
S304. performing a second etching process on the active layer to cause the active layer to have the predetermined pattern; and
step 304. stripping the third photoresist layer.

In the manufacturing method, the active layer is made by a printing method.

In the manufacturing method, the material of the active layer is carbon nanotube.

In the manufacturing method, the ohmic contact layer is made by a solution of the carbon nanotube doped with electrons.

In the manufacturing method, the carbon nanotube is a single-walled carbon nanotube, a double-walled carbon nanotube or a carbon nanotube bundle.

In the manufacturing method, the second metal layer is formed as a source/drain of the array substrate.

The present disclosure providing an array substrate, wherein the array substrate is made by the following methods, the manufacturing method includes:
S10. providing a substrate, forming a first metal layer on the substrate, and forming a gate of the array substrate on the substrate via a patterning process;
S20. forming a gate insulating layer on the gate;
S30. forming an active layer on the gate insulating layer;
S40. forming a first photoresist layer having a predetermined pattern on the active layer;
S50. forming an ohmic contact layer and second metal layer on the first photoresist layer sequentially,
wherein, the ohmic contact layer is made by a solution of the carbon nanotube, which including an electron doping;
S60. stripping the first photoresist layer; and
S70. forming a passivation layer on the second meatal layer.

In the array substrate of the present disclosure, the step S10 includes:
S101. providing the substrate, forming the first metal layer on the substrate;
S102. forming a second photoresist layer on the first metal layer;
S103. exposing and developing the second photoresist layer;
S104. performing a first etching process on the first metal layer, to cause the first metal layer to form the gate of the array substrate; and
S105. stripping the second photoresist layer.

In the array substrate, the active layer is made by a printing method.

In the array substrate, the material of the active layer is carbon nanotube.

In the array substrate, the carbon nanotube is a single-walled carbon nanotube, a double-walled carbon nanotube or a carbon nanotube bundle.

In the array substrate of the present disclosure, the second metal layer is formed as a source/drain of the array substrate.

The present disclosure also providing a display panel, includes an array substrate, wherein the array substrate is made by a manufacturing method, which includes:
S10. providing a substrate, forming a first metal layer on the substrate and, forming a gate of the array substrate on the substrate via a patterning process;
S20. forming a gate insulating layer on the gate;
S30. forming an active layer on the gate insulating layer;
S40. forming a first photoresist layer having a predetermined pattern on the active layer;
S50. forming an ohmic contact layer and second metal layer on the first photoresist layer sequentially,
wherein, the ohmic contact layer is made by a solution of the carbon nanotube, which including an electron doping;
S60. stripping the first photoresist layer; and
S70. forming a passivation layer on the second meatal layer.

In the display panel, the active layer is made by a printing method.

In the display panel, the material of the active layer is carbon nanotube.

In the display panel, the carbon nanotube is a single-walled carbon nanotube, a double-walled carbon nanotube or a carbon nanotube bundle.

In the display panel, the second metal layer is formed as a source/drain of the array substrate.

Effective result: through forming a first photoresist layer which having a predetermined pattern on the active layer, and forming an ohmic contact layer and second metal layer on the first photoresist layer sequentially. Simultaneous stripping of the first photoresist layer and the useless ohmic contact layer and the second metal layer on the first photoresist layer by a stripping process, by a mask process, to cause the ohmic contact layer and the second metal layer to have the predetermined pattern. It simplifies the preparing process and reduces the cost.

### BRIEF DESCRIPTION OF THE DRAWINGS

In order to clearly illustrate the embodiments and technical solutions in the prior art, brief description of the drawings are used in the embodiments or the description of prior art will be given below. Obviously, the drawings in the following description are only some embodiments of the invention. In the case of without providing creative work, those of ordinary skill in the art can obtain other drawings according to these drawings.

FIG. 1 is a flow chart of a manufacturing method of an array substrate according to the present disclosure;

FIGS. 2A-2J are cross-sectional views showing the array substrate in different steps of the manufacturing method according to the present disclosure.

### DETAILED DESCRIPTION OF THE EMBODIMENTS

The following description of each embodiment refers to the additional drawings, in order to illustrate the specific embodiments that may be implemented by the present disclosure. The directional terms mentioned in this invention, such as [upper], [lower], [front], [post], [left], [right], [inside], [outside], [side], etc., are only refers to the direction of the additional drawings. Therefore, the terms are used to illustrate and understand the present invention, not to limit the present invention. In the drawings, structurally similar elements are denoted by the same reference numerals.

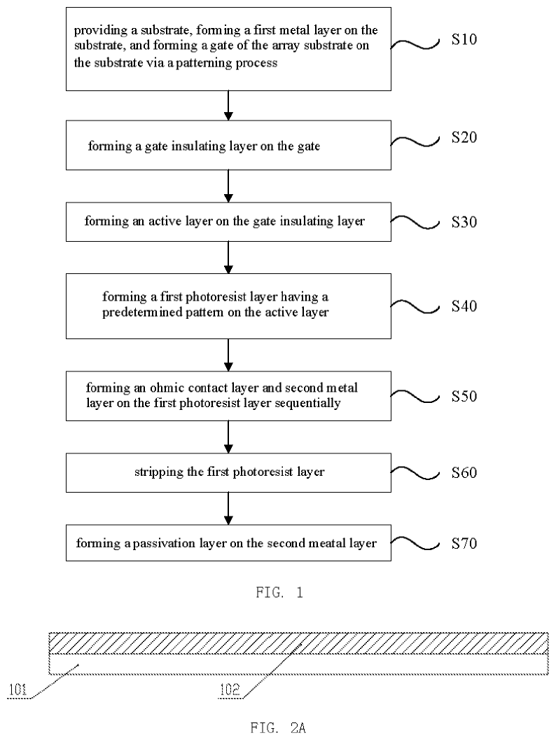

The FIG. 1 is a flow chart of a manufacturing method of an array substrate according to the present disclosure, wherein the manufacturing method includes steps: Step S10, provide g a base substrate, form a first metal layer on the base substrate, and form a gate of the array substrate on the base substrate via a patterning process.

First, base substrate 101 is provided. The raw material of the base substrate 101 may be one of a glass substrate, a quartz substrate, a resin substrate, etc.

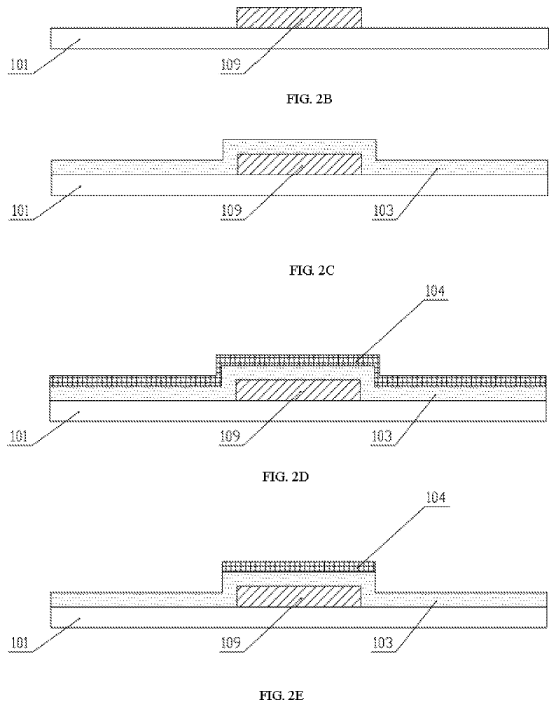

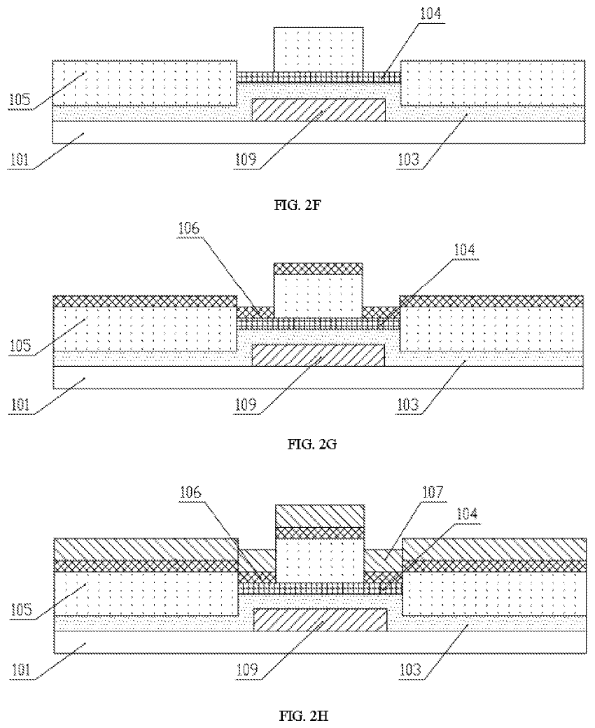

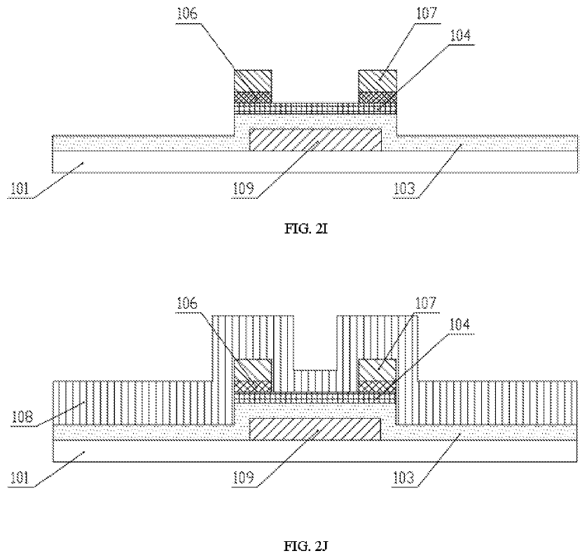

As shown in FIG. 2A, a first metal layer 102 is formed on the base substrate 101. The metal material of the first metal layer 102 may generally be a metal such as molybdenum, aluminum, aluminum-nickel alloy, molybdenum-tungsten alloy, chromium, or copper, or a combination of the above-mentioned metal materials.

Second, a first photomask process is applied to the first metal layer 102. A second photoresist layer (not shown) is coated on the first metal layer 102, and then the second photoresist layer is exposed by using a mask (not shown). After the development and the patterning process of the first etching, the first metal layer 102 is formed into a gate 109 as shown in FIG. 2B, and the second photoresist layer is stripped.

In addition, the gate of the array substrate may also be formed by printing of other conductive materials that can be made into ink.

Step S20, form a gate insulating layer on the gate.

As shown in FIG. 2C, the gate insulating layer 103 covers the gate 109 and the base substrate 101, and the gate insulating layer 103 is mainly used to isolate the gate from other metal layers. Preferably, the material of the gate insulating layer 103 is usually silicon nitride and it is possible to use silicon oxide, silicon oxynitride or the like. The thickness of the gate insulating layer 103 is no less than 2000 Å.

Step S30, form an active layer on the gate insulating layer.

As shown in FIG. 2E, in this step, a patterned active layer 104 may be formed on the gate insulating layer 103 by a printing method, and the active layer 104 is made of a carbon nanotube material.

It can be understood that the active layer 104 can be obtained by a more conventional process: first, an active layer 104 as shown in FIG. 2D is coated on the gate insulating layer 103, and a second mask process is used on the active layer. A third photoresist layer (not shown in the figures) is coated on the active layer, and then the third photoresist layer is exposed by using a mask (not shown in the figures). Thereafter, through development, etching, and photoresist stripping, the active layer 104 having a shape as shown in FIG. 2E is obtained, wherein, the etching of the active layer can be chosen from dry etching, and the gate insulating layer 103 is mainly etched by the plasma, and the plasma is one or a mixture of nitrogen tetrafluoride, sulfur hexafluoride, oxygen, or the like.

Step S40, form a first photoresist layer having a predetermined pattern on the active layer; in this step, first of all, a first photoresist layer is formed on the active layer 104, and the first photoresist layer covers the active layer 104 and the gate insulating layer 103, and then the first photoresist layer is exposed by using a mask (not shown in the figures), and the first photoresist layer 105 as shown in FIG. 2F is obtained.

Step S50, form an ohmic contact layer and a second metal layer on the first photoresist layer sequentially.

As shown in FIG. 2G, an ohmic contact layer 106 is formed on the first photoresist layer 105, and the ohmic contact layer 106 is made by a solution of the carbon nanotube doped with electrons. The ohmic contact layer 106 covers the first photoresist layer 105 and the active layer 104; the ohmic contact layer 106 may also be referred to as a doped layer because the active layer 104 is constituted by a weak n-type semiconductor material, and the direct contact of such a material with the metal film will create a Schottky barrier and degrade the electrical properties of the array substrate device, and cause an abnormality in the illumination of the display panel; therefore, the ohmic contact layer 106 is pre-deposited between the active layer 104 and a second metal layer 107 to be deposited, thereby preventing the second metal layer 107 from directly contacting the active layer 104;

In addition, in the embodiment, the carbon nanotube used as the material of the active layer 104 and the ohmic contact layer 106 may be a single-walled carbon nanotube, a double-walled carbon nanotube or a carbon nanotube bundle. The nanotube carbon can be used in the preferred embodiment by dispersing it in a suitable organic solvent.

As shown in FIG. 2H, the second metal layer 107 is formed on the base substrate 10. The first metal layer 102 and the second metal layer 107 may be formed by the method of sputtering or physical deposition. In the embodiment, the material of the second metal layer 107 and the material of the first metal layer 102 may be the same or different. The metal material can usually be a metal such as molybdenum, aluminum, aluminum-nickel alloy, molybdenum-tungsten alloy, chromium, or copper, or a combination of the above-mentioned metal materials.

Step S60, strip the first photoresist layer.

In this step, it mainly strips the first photoresist layer 105 on the base substrate 101 by a stripping process. When the first photoresist layer 105 is stripped, the ohmic contact layer 106 and the second metal layer 107 on the first photoresist layer 105 are stripped together, and the structures of ohmic contact layer 106 and the second metal layer 107 are obtained as shown in FIG. 2I, wherein the second metal layer 107 formed as a source/drain of the array substrate. In the embodiment, the stripping method can be carried out by using a photoresist stripping solution.

Step S70, form a passivation layer on the second meatal layer.

As shown in FIG. 2J, a passivation layer 108 is formed on the second metal layer 107. The passivation layer 108 covers the gate insulating layer 103, the active layer 104 and the second metal layer 107; preferably, the material of the passivation layer 108 is usually a tantalum nitride compound.

An array substrate is provided, wherein the array substrate is prepared by the above manufacturing method of the array substrate.

A display panel is provided, wherein the display panel includes the above array substrate.

An array substrate, a manufacturing method, and a display panel thereof are provided. The method includes, first of all, forming a gate layer, a gate insulating layer, an active layer on a base substrate, forming a first photoresist layer having a predetermined pattern on the active layer, and forming an ohmic contact layer and a second metal layer on the first photoresist layer sequentially, and simultaneously stripping the first photoresist layer and the ohmic contact layer and the second metal layer which are on the first photoresist layer. The ohmic contact layer and the second metal layer are formed into a predetermined pattern by a single photomask processing. The present disclosure simplifies the preparing process of the array substrate and reduces the cost.

In summary, although the present disclosure has been disclosed in the above embodiments, the above embodiments are not used to limit the present disclosure. A person skilled in the art can make various modifications and refinements without departing from the spirit and scope of the present disclosure, and the scope of protection of the present disclosure is defined by the claims.

What is claimed is:

1. A manufacturing method for array substrate, comprising:
S10. providing a substrate, forming a first metal layer on the substrate, and forming a gate of the array substrate on the substrate via a patterning process;
S20. forming a gate insulating layer on the gate;
S30. forming an active layer on the gate insulating layer;
S40. forming a first photoresist layer having a predetermined pattern on the active layer;
S50. forming an ohmic contact layer and second metal layer on the first photoresist layer sequentially;
S60. stripping the first photoresist layer; and
S70. forming a passivation layer on the second meatal layer.

2. The manufacturing method as claimed in claim 1, wherein the step S10 comprises:
S101. providing the substrate, forming the first metal layer on the substrate;
S102. forming a second photoresist layer on the first metal layer;
S103. exposing and developing the second photoresist layer;
S104. performing a first etching process on the first metal layer to cause the first metal layer to form the gate of the array substrate; and
S105. stripping the second photoresist layer.

3. The manufacturing method as claimed in claim 1, wherein the step S30 comprises:
S301. forming the active layer on the gate insulating layer;
S302. exposing and developing the third photoresist layer;
S304. performing a second etching process on the active layer to cause the active layer to have the predetermined pattern; and
step 304. stripping the third photoresist layer.

4. The manufacturing method as claimed in claim 1, wherein the active layer is made by a printing method.

5. The manufacturing method as claimed in claim 1, wherein the material of the active layer is carbon nanotube.

6. The manufacturing method as claimed in claim 1, wherein the ohmic contact layer is made by a solution of the carbon nanotube doped with electrons.

7. The manufacturing method as claimed in claim 6, wherein the carbon nanotube is a single-walled carbon nanotube, a double-walled carbon nanotube or a carbon nanotube bundle.

8. The manufacturing method as claimed in claim 1, wherein the second metal layer is formed as a source/drain of the array substrate.

9. An array substrate, wherein the array substrate is made by a manufacturing method, which comprises:
S10. providing a substrate, forming a first metal layer on the substrate, and forming a gate of the array substrate on the substrate via a patterning process;
S20. forming a gate insulating layer on the gate;
S30. forming an active layer on the gate insulating layer;
S40. forming a first photoresist layer having a predetermined pattern on the active layer;
S50. forming an ohmic contact layer and second metal layer on the first photoresist layer sequentially,
wherein, the ohmic contact layer is made by a solution of the carbon nanotube, which including an electron doping;
S60. stripping the first photoresist layer; and
S70. forming a passivation layer on the second meatal layer.

10. The array substrate as claimed in claim 9, wherein the step S10 comprises:
S101. providing the substrate, forming the first metal layer on the substrate;
S102. forming a second photoresist layer on the first metal layer;
S103. exposing and developing the second photoresist layer;
S104. performing a first etching process on the first metal layer, to cause the first metal layer to form the gate of the array substrate; and
S105. stripping the second photoresist layer.

11. The array substrate as claimed in claim 9, wherein the active layer is made by a printing method.

12. The array substrate as claimed in claim 9, wherein the material of the active layer is carbon nanotube.

13. The array substrate as claimed in claim 12, wherein the carbon nanotube is a Single-walled carbon nanotube, a double-walled carbon nanotube or a carbon nanotube bundle.

14. The array substrate as claimed in claim 9, wherein the second metal layer is formed as a source/drain of the array substrate.

15. A display panel, comprising an array substrate, wherein the array substrate is made by a manufacturing method, which comprises:
S10. providing a substrate, forming a first metal layer on the substrate and, forming a gate of the array substrate on the substrate via a patterning process;
S20. forming a gate insulating layer on the gate;
S30. forming an active layer on the gate insulating layer;
S40. forming a first photoresist layer having a predetermined pattern on the active layer;
S50. forming an ohmic contact layer and second metal layer on the first photoresist layer sequentially,
wherein, the ohmic contact layer is made by a solution of the carbon nanotube, which including an electron doping;
S60. stripping the first photoresist layer; and
S70. forming a passivation layer on the second meatal layer.

16. The display panel as claimed in claim 15, wherein the active layer is made by a printing method.

17. The display panel as claimed in claim 15, wherein the material of the active layer is carbon nanotube.

18. The display panel as claimed in claim 15, wherein the carbon nanotube is a Single-walled carbon nanotube, a double-walled carbon nanotube or a carbon nanotube bundle.

19. The display panel as claimed in claim 17, wherein the second metal layer is formed as a source/drain of the array substrate.
